(19) United States
(12) Patent Application Publication
(10) Pub. No.: US 2007/0069397 A1
(43) Pub. Date: Mar. 29, 2007

(54) Coil construction

(75) Inventors: Steven Jan Willem Van Lerberghe, EINDHOVEN (NL); Petrus Paulus Van De Mortel, Eindhoven (NL)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(73) Assignee: KONINKLIJKE PHILIPS ELECTRONICS N.V., EINDHOVEN (NL)

(21) Appl. No.: 10/575,770

(22) PCT Filed: Oct. 5, 2004
(86) PCT No.: PCT/IB04/51974

§ 371 Date: Apr. 12, 2006

(30) Foreign Application Priority Data
Oct. 16, 2003 (EP) 03103842.5

(51) Int. Cl. H01L 23/52

(52) U.S. Cl. 257/784

(57) ABSTRACT

A coil comprises a layer of permeable material (4) deposited in a chip (CH) of an integrated circuit (IC) in a plane substantially parallel to a surface (A) of a substrate (1) of the chip (CH). A first conductor element (6a, 6b; BW10, BWI 1; 60a, 60b) is arranged at a first side of the permeable material (4) facing away from the substrate (1). A second conductor element (2a, 2b; T1, T2) is arranged at a second side of the permeable material (4) opposite to the first side. An interconnection (8a, 8b; P2, P4) interconnects a first end of the first conductor element (6a, 6b; BW10, BWI 1; 60a, 60b) and a first end of the second conductor element (2a, 2b; T1, T2). The interconnection (8a, 8b; P2, P4), the first conductor element (6a, 6b; BW10, BW11; 60a, 60b) and the second conductor element (2a, 2b; T1, T2) are arranged to form a winding around the permeable material (4). The winding extends in a plane substantially perpendicular to the surface (A) of the substrate (1) to conduct current (1) in a plane substantially perpendicular to the surface (A) of the substrate (1).

The invention relates to a coil, an integrated circuit, an arrangement of an integrated circuit and a printed circuit board for forming such a coil, an electronic apparatus comprising such a coil, and a two-dimensional antenna comprising such a coil and a further coil. The coil is at least partly formed with elements integrated in the integrated circuit.

Such a small and inexpensive coil is in particular useful for induction of energy in high frequent (RF) tags. Further, such a coil can be used as an antenna in personal area networks.

JP-A-2001-284533 discloses an on-chip coil. The chip comprises a substrate on which a first insulation layer is formed. A first spiral winding is provided on the first insulation layer in a plane parallel to the substrate surface. A second insulation layer is provided on the first spiral winding. A second spiral winding which has the same shape as the first spiral winding is arranged on top of the second insulation layer. The second spiral winding is aligned with the first spiral winding such that they are on top of each other. In the second insulation layer, between the first and second spiral winding, relatively small holes are formed which are filled with ferroelectric material to conductively interconnect the first and second spiral winding. In the center of the first and second spiral winding, a relatively large hole is formed in the second insulation layer which is filled with the ferroelectric material to form a magnetic core for the parallel arranged first and second spiral winding. The electrically and mechanically parallel arranged first and second spiral winding together with the magnetic core constitute a compact on-chip coil with a high inductance due to the magnetic core, and a low resistance due to the parallel arrangement of the two spiral windings.

The axis of this coil is directed perpendicular on the substrate surface. If energized, such a coil generates a magnetic field substantially perpendicular on the plane of the substrate surface. Or, if used as an antenna, such a coil is most sensitive to a magnetic field component perpendicular on the plane of the substrate surface and is insensitive to a magnetic field in the plane of the substrate surface.

It is a drawback of this coil that the size of the magnetic core is relatively small.

It is an object of the invention to provide a coil which is at least partly integrated in a chip and which comprises a magnetic core with a larger volume.

A first aspect of the invention provides a coil as claimed in claim 1. A second aspect of the invention provides an integrated circuit as claimed in claim 12. A third aspect of the invention provides an arrangement of an integrated circuit and a printed circuit board as claimed in claim 16. A fourth aspect of the invention provides an electronic apparatus as claimed in claim 17. A fifth aspect of the invention provides a two-dimensional antenna as claimed in claim 19. Advantageous embodiments are defined in the dependent claims.

The coil comprises a layer of permeable material being deposited in an integrated circuit in a plane substantially parallel to a surface of a substrate of a chip. The integrated circuit is defined as the arrangement of the actual chip which comprises the electronic elements, bond wires and the encasing of the chip with connectors to the outside world of the integrated circuit. A first conductor element is arranged at a first side of the permeable material being directed away from the substrate. A second conductor element is arranged at a second side of the permeable material opposite to the first side. An interconnection interconnects a first end of the first conductor and a first end of the second conductor. The interconnection, the first conductor and the second conductor are arranged to form a one turn winding around the permeable material. The winding is arranged in a plane substantially perpendicular to the surface of the substrate to conduct current in a plane extending substantially perpendicular to the substrate surface. In contrast, the current in the spiral winding of JP-A-2001-284533 flows substantially in parallel to the substrate surface.

The coil realized in accordance with this aspect of the invention comprises a permeable material that is sandwiched between the first and the second conductor element.

The permeable material is the core of the coil, the first and second conductor element form a winding around the core. Thus, the core is in-between the first and second conductor element and thus, the dimensions of the permeable material are not restricted to a central area of a spiral winding. Preferably, the permeable material is ferrite.

In a preferred embodiment as defined in claim 7, several first and second conductor elements are interconnected to provide a multi turn winding around the permeable material. The permeable material which is part of the chip is a layer arranged in parallel with the substrate surface. Preferably, the permeable material is deposited on an insulating layer. The interconnected first and second conductor elements form a helical shaped winding around the core. The helical shaped winding need not be circular. The first and/or second conductor elements may be flat and may extend in a plane substantially parallel with the substrate surface. The interconnections may be arranged substantially perpendicular to the substrate surface. Such a coil has an axis which is parallel to the substrate surface. The axis might be straight or curved.

In an embodiment as defined in claim 10, if energized, such a coil will generate a magnetic field substantially in a plane parallel to the substrate surface.

In an embodiment as defined in claim 1, if used as an antenna, the coil is most sensitive to magnetic field components in the plane parallel to the substrate surface.

In an embodiment as defined in claim 2, the first conductor element is part of the integrated circuit. This has the advantage that it is not required to provide this conductor outside the integrated circuit. It is possible to provide a plurality of first conductor elements to obtain a coil with a winding which has a plurality of turns.

In an embodiment as defined in claim 3, the first conductor element is a bond wire in the integrated circuit. The bond wire is arranged across the permeable material at the side of the permeable material facing away from the substrate.

In an embodiment as defined in claim 4, the first conductor element is a conductive track on the chip. In a preferred embodiment, this conductive track is arranged on an insulating layer covering the permeable material at the side facing away from the substrate.

In an embodiment as defined in claim 5, the second conductor element is part of the chip and is arranged between the permeable material and the substrate. Preferably, the second conductor element is deposited on an insulating layer provided on the substrate. It is possible to provide a plurality of second conductor elements which are interconnected with the plurality of first conductor elements to obtain a coil with a winding which has a plurality of turns.

If both the first and second conductor element(s) are conductive tracks deposited on the chip, the interconnections are made on chip with via's through the insulating layers. If the first conductor element is a bond wire, the interconnection is made via a bond pads and a via.

In an embodiment as defined in claim 6, the second conductor element is arranged on a printed circuit board which carries the integrated circuit. The interconnection is made via a pen of the integrated circuit, a bond wire, a bond pad and a via

In an embodiment as defined in claim 8, the first conductor elements are arranged substantially in parallel. This is an efficient manner to arrange many first conductor elements above the permeable material.

In an embodiment as defined in claim 9, the second conductor elements are arranged substantially in parallel. This is an efficient manner to arrange many second conductor elements below the permeable material.

In a preferred embodiment both the first and second conductor elements are arranged substantially in parallel to obtain a winding which closely resembles a wire wound coil.

In the second aspect of the invention, the integrated circuit comprises the chip. The chip comprises the substrate, the layer of permeable material deposited in a plane substantially parallel to the surface of the substrate. The integrated circuit further comprises the first conductor element which is arranged at a first side of the permeable material facing away from the substrate. Further, to obtain the coil, the second conductor element is arranged at a second side of the permeable material opposite to the first side, and the interconnection is provided to interconnect a first end of the first conductor and a first end of the second conductor. Thus the integrated circuit comprises at least the first conductor element and the permeable material, and part of the interconnection. The actual implementation of the interconnection depends on the actual construction of the first conductor (bond wire or track on the chip) and the second conductor (track on a printed circuit board or track on the chip).

In an embodiment as defined in claim 13, also the second conductor is part of the chip. This provides a very compact coil completely present in the integrated circuit.

These and other aspects of the invention are apparent from and will be elucidated with reference to the embodiments described hereinafter.

In accordance with the fifth aspect, the coil in accordance with the invention is combined with a known spiral coil in a plane in parallel with the surface of the substrate. This ferrite element is used. for the coil in accordance with the invention by providing a winding with turns around the ferrite element such that these turns lie in a plane substantially perpendicular to the surface. This coil in accordance with the invention generates a magnetic field or is most sensitive to a magnetic field substantially parallel to the surface. The same ferrite element is also used as the central core of a known spiral coil of which the turns lie in a plane parallel to the surface. This coil generates a magnetic field or is most sensitive to a magnetic field substantially perpendicular to the surface. In this manner it is possible to obtain a two-dimensional antenna while only a single piece of ferrite is required. The ferrite element, or the single piece of ferrite is deposited as a layer in the chip.

In the drawings:

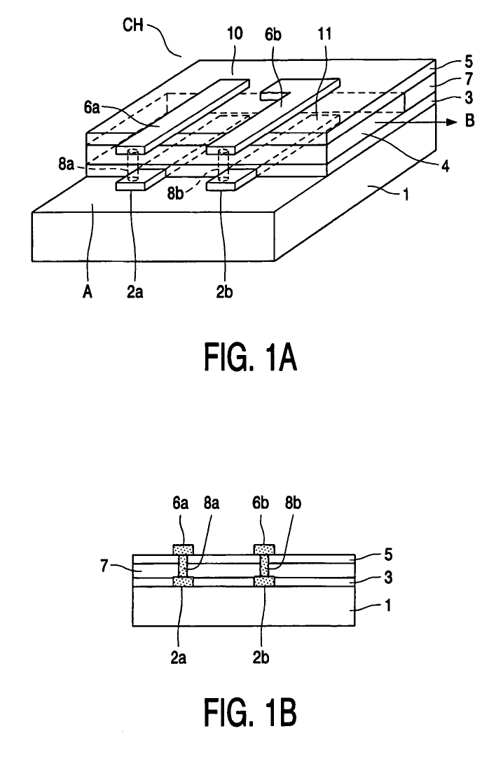

FIG. 1 shows several views of a chip comprising a coil in accordance with an embodiment of the invention,

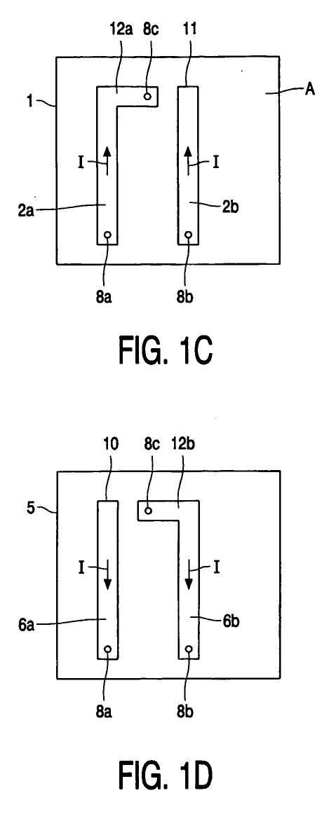

FIG. 2 shows a view of a coil formed by a chip and tracks on a printed circuit board of another embodiment in accordance with the invention,

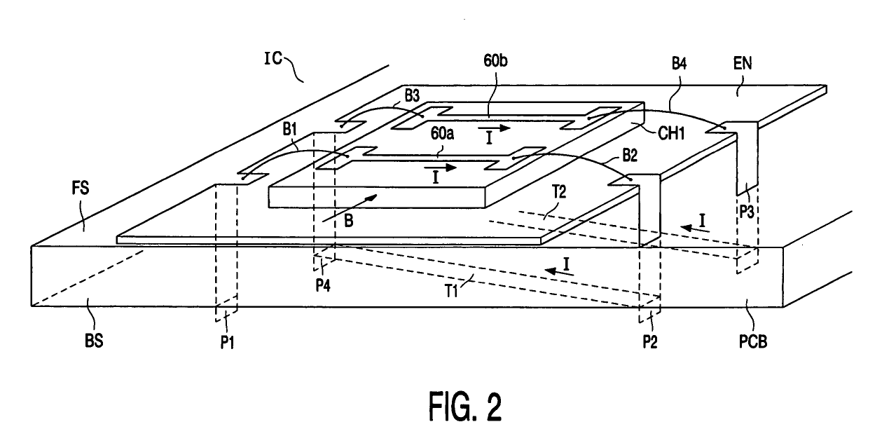

FIG. 3 shows a view of a chip comprising a coil in accordance with another embodiment of the invention, and

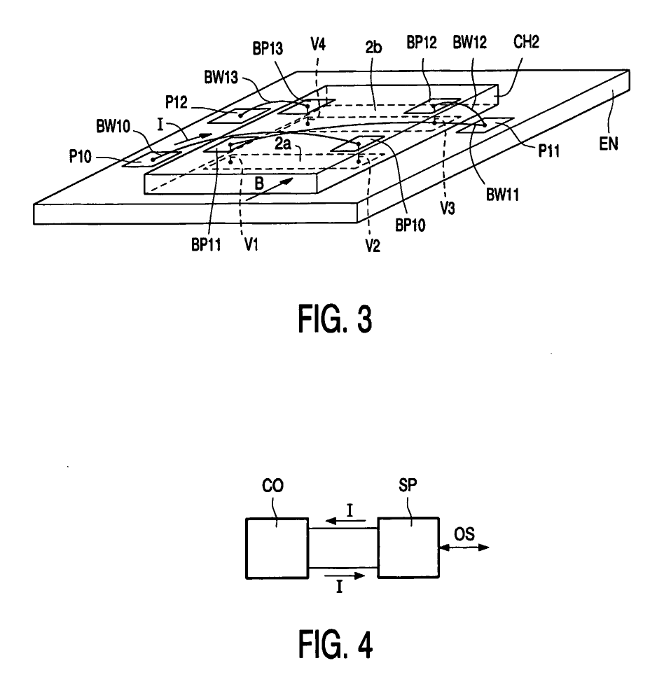

FIG. 4 shows an apparatus comprising such a coil.

The same references in different FIGS. refer to the same elements or signals.

FIG. 1 shows several views of a chip comprising a coil in accordance with an embodiment of the invention. FIG. 1A shows a partly opened chip. FIG. 1B shows a front view of the partly opened chip. FIG. 1C shows a top view of the second conductor elements, and FIG. 1D shows a top view of the first conductor elements.

FIG. 1A shows a chip CH which comprises from bottom to top the next stack of layers: a substrate I with a surface A, second conductor elements 2a, 2b deposited on the surface A and covered by an insulating layer 3, a permeable layer 4 deposited on the insulating layer 3 and flanked by an insulating layer 7, an insulating layer 5 deposited on the permeable layer 4, and first conductor elements 6a, 6b deposited on the insulating layer 5. The chip CH is partly open to show the interconnections 8a, 8b which interconnect ends of the first conductor elements 6a, 6b with ends of the second conductor elements 2a, 2b . These interconnections 8a, 8b are conductive via's which are provided in a known manner.

The coil shown by way of example has two turns arranged around a core which is the permeable layer 4. The first turn is realized by the first conductor element 6a, the interconnection 8a and the second conductor element 2a. The second turn is realized by the first conductor element 6b, the interconnection 8b and the second conductor element 2b . The two turn coil has connections 10 and 11. In an actual implementation, the number of turns may vary between I and a high number, limited by the dimensions of the conductor elements 2a, 2b, 6a, 6b and the dimensions of the chip CH. It is not required that the number of turns is an integer. For example, the second conductor element 2b may be omitted. The permeable material 4, which preferably is a ferrite, preferably fills the space between the first conductor elements 6a, 6b and the second conductor elements 2a, 2b maximally to obtain a maximum volume of the permeable material 4.

The first conductor elements 6a, 6b extend substantially in parallel with each other. Also the second conductor elements 2a, 2b extend substantially in parallel with each other. In FIG. 1A, by way of example, both the first and the second conductor elements 6a, 6b, 2a, 2b all extend in the same direction parallel to one of the edges of the substrate 1. All the first and the second conductor elements 6a, 6b, 2a, 2b may also extend in a same direction which is not parallel to an edge of the substrate 1. The parallel arranged first conductor elements 6a, 6b may also have an angle with respect to the parallel arranged second conductor elements 2a, 2b . For example, the conductor element 6b may be a straight element of which one end is in the position shown in FIG. 1A to cooperate with the interconnection 8b. With respect to the situation shown in FIG. 1A, the straight element 6b is rotated around the interconnection 8b such that the other end is at the position of the connection 10 in FIG. 1A to be connected via the interconnection 8c to a straight second conductor element 8a. The first conductor element 6a has to rotate around the interconnection 8a to become parallel with the first conductor element 6b. Alternatively, the second conductor element 2a may be straight and may be rotated around the interconnection 8a such that the other end of this second conductor element 2a cooperates via the interconnection 8c with a straight first conductor element 6b. Of course, other constellations of the first and second conductor elements 6a, 6b, 2a, 2b are possible. What counts is that the conductor elements 6a, 6b, 2a, 2b form turns of a winding around the permeable material, which turns are not arranged in a plane parallel to the surface A but perpendicular to this surface A. Such a coil construction has the advantage that it allows the use of a relatively large volume of the permeable material. If this coil is energized by supplying a current I through it, it will generate a magnetic field B which is directed substantially in parallel with the surface A. If the coil is an antenna, the coil will have its maximum sensitivity for a magnetic field occurring in a plane parallel to the surface A. A magnetic field perpendicular to the surface A will induce substantially no current into the coil.

FIG. 1B shows the stack of layers and the interconnections 8a, 8b between the first conductor element 6a, 6b and the second conductor elements 2a, 2b. The insulating layers 3 and 7 may be deposited as a single layer.

FIG. 1C shows an embodiment of the second conductor elements 2a, 2b on the surface A of the substrate 1. FIG. 1D shows an embodiment of the first conductor elements 6a, 6b on the insulating layer 5. Both in FIG. 1C and FIG. 1D, the interconnections 8a, 8b, 8c, for clarity only, are indicated by small circles. The second conductor element 2a has a protrusion 12a to allow interconnecting it via the interconnection 8c to the protrusion 12b of the first conductor element 6b. The arrows indicate the direction of the current I in the conductor elements 2a, 2b, 8a, 8b. This current I may be induced by a varying magnetic field B received by the coil. The current I may be supplied to the coil via the connections 10 and 11 to generate the magnetic field B. All currents I may have the opposite direction.

FIG. 2 shows a view of a coil formed by a chip and tracks on a printed circuit board of another embodiment in accordance with the invention. The chip CH1 is based on the chip CH of FIG. 1. The second conductor elements 2a, 2b are removed. These second conductor elements are now tracks T1, T2 on a printed circuit board PCB. The first conductor elements are now indicated by 60a and 60b. Of the housing of the chip CHI only the bottom plate EN is shown. In practice the housing of the chip CH1 encapsulates the chip CH1 completely. Four pins P1, P2, P3, P4 of the integrated circuit 1C are shown. These pins P1, P2, P3, P4 are soldered to the back surface BS of the printed circuit board PCB. The pin P1 is one of the connections of the coil and is connected via a bond wire B1 to one end of the first conductor element 60a. The other end of the first conductor element 60a is connected via a bond wire B2 to the pin P2. The track T1 on the printed circuit board PCB connects the pin P2 with the pin P4. The pin P4 is connected to one end of the first conductor 60b via the bond wire B3. The other end of the first conductor 60b is connected via a bond-wire B4 to a pen P3 which is the other connection of the coil. An extra half of a turn is obtained if the track T2 on the printed circuit board PCB is provided which goes back to the side of the chip where the pins P1 and P4 are situated. In the same manner, it is possible to provide a coil with only one turn or with more than two turns. If this coil is energized with the current I of which the direction is indicated by the arrows near the reference I, a magnetic field B will be generated in the direction of the arrow near the reference B. The polarity of the current I and the field B may be opposite. Preferably, an alternating current I is used. The coil may also be used to receive the magnetic field B. The integrated circuit IC comprises the chip CH1, the bond wires B1 to B4 and the pins P1 to P4. Usually, the integrated circuit IC is attached to the printed circuit board by soldering the pins P1 to P4 to tracks on the back surface BS of the printed circuit board PCB.

Many alternative constructions may be implemented. For example, the tracks T1 and T2 may be positioned on the front surface FS of the printed circuit board PCB, and the integrated circuit IC may be attached to the printed circuit board by soldering the pins P1 to P4 to the tracks at the front surface FS. The IC need not have pins, but may have contact areas which are pressed on corresponding tracks or contact areas on the printed circuit board PCB.

FIG. 3 shows a view of a chip comprising a coil in accordance with another embodiment of the invention. The chip CH2 is based on the chip CH of FIG. 1. The first conductor elements 6a, 6b are not present in the chip CH2. These first conductor elements are now bond wires BW10, BW11 of the integrated circuit IC. FIG. 3 shows only the bottom plate EN of the housing of the chip CHI. In practice the housing of the chip CH1 encapsulates the chip CH1 completely. Only the tops of the pins P10, to P12 of the integrated circuit IC are shown. The pin P10 is a connection of the coil. The pin P10 is connected via a bond wire BW10 to a bond pad BP10. The bond pad BP10 is connected via an interconnection or via V2 to one end of the second conductor element 2a. The other end of the second conductor element 2a is connected via the via VI to the bond pad BP11. The bond wire BW10 and the second conductor element 2a thus form a turn around the permeable material 4 (not shown in FIG. 3). The bond pad BP11 is connected to a pin P11 via a bond wire BW11. It would also be possible to provide a bond wire directly between the bond pads BP11 and BP12. The pin P11 is connected via a bond wire BWI2 to the bond pad BP12. The bond pad BP12 is connected via a via V3 to the one end of the second conductor element 2b. The other end of the second conductor element 2b is connected via a via V4 to a bond pad BP13. The bond pad BP13 is connected via a bond wire BW13 to the pin P12 which is a connection of the coil. The bond wire BW11 and the second conductor element 2b form the second turn of the coil. The connections P10, P12 of the coil may be made to circuitry outside the integrated circuit IC. However, these connections may actually not be used as the circuitry connected to the coil may be present in the chip CH2. The arrow near the reference B indicates that the coil realized in this manner generates a magnetic field in a plane which is parallel to the plane of the surface A of the substrate 1 and thus in the plane the substrate 1 extends.

FIG. 4 shows an apparatus comprising such a coil. The apparatus comprises the coil CO and a signal processing circuit SP. If the coil is used to generate a magnetic field B, the signal processing circuit SP supplies a current to the coil CO in response to a signal OS. For example, the coil may generate an electromagnetic field in a wireless system. The signal processing circuit SP generates a high frequent signal which is modulated to contain the signal OS. If the coil is used to receive an electromagnetic field, the signal processing circuit SP retrieves the signal OS which is modulated on a high frequent carrier.

Such a coil can be used in any application in which a transmitting and/or receiving antenna is required. For example, the coil in accordance with the invention may be used in high frequent (RF) tags, in personal area networks, or a very low power magnetic coupling (AURA), or in test chips.

It should be noted that the above-mentioned embodiments illustrate rather than limit the invention, and that those skilled in the art will be able to design many alternative embodiments without departing from the scope of the appended claims. Although the embodiments elucidate the invention for a coil with two turns, the invention is not restricted to coils having exactly two turns. The same approach is possible if the coil comprises a single turn or more than one turn. It is not required that the number of turns is exactly an integer. Relevant is that the coil in accordance with the invention has a winding with at least one turn which, when energized, generates a magnetic field in a plane substantially parallel to the surface of the substrate of a chip on which at least the permeable material is deposited. The integrated circuit which comprises the chip comprises at least one set of conductor elements which together with a second set of conductor elements which may be positioned on the chip or outside the integrated circuit, and interconnections form the turns of the coil.

It is possible to combine the coil in accordance with the invention with a magnetic lens, or to provide two perpendicular arranged antennas with two orthogonal arranged coils in accordance with the invention. If multiple coils/antennas are presents it is possible to switch to the coil/antenna which gives the best signal condition. If the coil/antenna is completely integrated in the integrated circuit IC, no external connections or components are required and an excellent impedance matching between the coil/antenna and the on-chip circuitry is possible. Further, the spread of the magnetic field will be very small. The coil/antenna may be used to induce magnetic energy into RF-tags or chips in disc like functions either by a varying magnetic field or by permanent magnets. This magnetic energy is used to generate a power supply voltage in the receiver.

In the claims, any reference signs placed between parentheses shall not be construed as limiting the claim. Use of the verb “comprise” and its conjugations does not exclude the presence of elements or steps other than those stated in a claim. The article “a” or “an” preceding an element does not exclude the presence of a plurality of such elements. The invention may be implemented by means of hardware comprising several distinct elements, and by means of a suitably programmed computer. In the device claim enumerating several means, several of these means may be embodied by one and the same item of hardware. The mere fact that certain measures are recited in mutually different dependent claims does not indicate that a combination of these measures cannot be used to advantage.

1. A coil comprising
a layer of permeable material deposited in a chip of an integrated circuit in a plane substantially parallel to a surface of a substrate of the chip,
a first conductor element arranged at a first side of the permeable material (4) facing away from the substrate,
a second conductor element arranged at a second side of the permeable material opposite to the first side,
an interconnection for interconnecting a first end of the first conductor element and a first end of the second conductor element wherein the interconnection the first conductor element and the second conductor element are arranged for forming a winding around the permeable material, the winding extending in a plane substantially perpendicular to the surface of the substrate.

2. A coil as claimed in claim 1, wherein the first conductor element is part of the integrated circuit.

3. A coil as claimed in claim 2, wherein the first conductor element comprises a bond wire.

4. A coil as claimed in claim 2, wherein the first conductor element comprises a conductive track on the chip.

5. A coil as claimed in claim 1, wherein the second conductor element comprises a conductive track on the chip and is arranged between the permeable material and the substrate.

6. A coil as claimed in claim 1, wherein the second conductor element comprises a conductive track arranged on a printed circuit board for carrying the integrated circuit.

7. A coil as claimed in claim 1, wherein
a plurality of first conductor elements is arranged at a first side of the permeable material facing away from the surface of the substrate,
a plurality of second conductor elements is arranged at a second side of the permeable material opposite to the first side, and
a plurality of interconnections being arranged for interconnecting the plurality of first conductor elements and the plurality of second conductor elements in a chain, wherein the interconnections the first conductor elements and the second conductor elements are arranged for forming a winding around the permeable material for conducting current (i) in turns of the winding being substantially perpendicular to the surface.

8. A coil as claimed in claim 7, wherein the first conductor elements are arranged substantially in parallel.

9. A coil as claimed in claim 7, wherein the second conductor elements are arranged substantially in parallel.

10. A coil as claimed in claim 1, wherein the coil, when energized, generates a magnetic field having a direction substantially parallel with the surface.

11. A coil as claimed in claim 1, wherein the coil is arranged for being most sensitive for a magnetic field component having a direction parallel with the surface.

12. An integrated circuit comprising:
the chip with a substrate the layer of permeable material deposited in the plane substantially parallel to the surface of the substrate and the first conductor element arranged at the first side of the permeable material facing away from the substrate
the second conductor element arranged at the second side of the permeable material opposite to the first side, and
the interconnection for interconnecting the first end of the first conductor and the first end of the second conductor element wherein the interconnection, the first conductor element and the second conductor element are arranged for forming the winding around the permeable material turns of the winding extending in a plane substantially perpendicular to the surface of the substrate to form a coil as claimed in claim 1.

13. An integrated circuit as claimed in claim 12, wherein the chip further comprises:
the second conductor element being deposited on the substrate and
an isolating layer for isolating the second conductor element from the permeable material the permeable material being deposited as a layer on the isolating layer.

14. An integrated circuit as claimed in claim 12, wherein the first conductor element comprises a bond wire.

15. An integrated circuit as claimed in claim 12, wherein the first conductor element comprises a conductive track on the chip the chip further comprises an isolating layer arranged in-between the permeable material and the first conductor element.

16. An arrangement of an integrated circuit and a printed circuit board for forming a coil as claimed in claim 1, wherein
the integrated circuit has at least one electrical conductive connection with the printed board
the chip comprises the layer of the permeable material,
the first conductor element is arranged at a first side of the permeable material facing away from the substrate,
the second conductor element is arranged on the printed circuit board and
the interconnection between the first conductor element and the second conductor element is made via the electrical conductive connection.

17. An electronic apparatus comprising a coil as claimed in claim 1.

18. An electronic apparatus as claimed in claim 17 being a tag.

19. A two-dimensional antenna comprising:
a coil as claimed in claim 1, and
a further coil comprising a conductor arranged around the layer of permeable material in a plane substantially parallel to the surface, wherein the layer of permeable material forms a core for both the first mentioned coil and the further coil.
